(19) United States
(12) Patent Application Publication
(10) Pub. No.: US 2024/0071924 A1
(43) Pub. Date: Feb. 29, 2024

(54) INTEGRATED CIRCUIT DEVICE INCLUDING INTERCONNECTION STRUCTURE

(71) Applicant: SAMSUNG ELECTRONICS CO., LTD., SUWON-SI (KR)

(72) Inventors: Jungil PARK, Suwon-si (KR); Jeonghoon AHN, Suwon-si (KR); Yunki CHOI, Suwon-si (KR)

(21) Appl. No.: 18/232,894

(22) Filed: Aug. 11, 2023

(30) Foreign Application Priority Data
Aug. 23, 2022 (KR) 10-2022-0105776

(51) Int. Cl. H01L 23/528; H01L 21/768; H01L 23/522; H01L 23/532

(52) U.S. Cl. CPC H01L 23/5283; H01L 21/76807; H01L 21/76816; H01L 23/5226; H01L 23/53295; H01L 21/76843; H01L 21/76876; H01L 21/76883; H01L 2221/1036

(57) ABSTRACT

An integrated circuit device includes an interconnection structure that includes: an interlayer insulating layer arranged on a substrate and having a plurality of trenches; a first conductive layer formed inside a first trench of the plurality of trenches; a second conductive layer formed inside a second trench of the plurality of trenches, wherein the second trench is spaced apart from the first trench; a third conductive layer formed inside a third trench of the plurality of trenches, wherein the third trench is spaced apart from the second trench; and a dielectric layer formed between the first conductive layer and the second conductive layer, wherein a portion of interlayer insulating layer is disposed between the second conductive layer and the third conductive layer, and wherein a first width of the first conductive layer is greater than a second width of the second conductive layer.

### CROSS-REFERENCE TO RELATED APPLICATION

This application claims priority under 35 U.S.C. § 119 to Korean Patent Application No. 10-2022-0105776, filed on Aug. 23, 2022, in the Korean Intellectual Property Office, the disclosure of which is incorporated by reference herein in its entirety.

### TECHNICAL FIELD

The present inventive concept relates to an integrated circuit device, and more particularly, to an integrated circuit device including an interconnection structure.

### DISCUSSION OF THE RELATED ART

An interconnection structure, of an integrated circuit device, for implementing the integrated circuit device has been under development to have a reduced size. However, it is difficult to reduce a distance between metal wirings due to the limitation of a photolithography process. With this limitation, the difficulty of a process for reducing the resistance of the metal wiring is increased.

### SUMMARY

The present inventive concept provides an interconnection structure of an integrated circuit device in which a distance between metal wirings is reduced.

According to an embodiment of the present inventive concept, an integrated circuit device includes an interconnection structure, wherein the interconnection structure includes: an interlayer insulating layer arranged on a substrate and having a plurality of trenches formed in the interlayer insulating layer; a first conductive layer formed inside a first trench of the plurality of trenches; a second conductive layer formed inside a second trench of the plurality of trenches, wherein the second trench is spaced apart from the first trench of the plurality of trenches in a first direction; a third conductive layer formed inside a third trench of the plurality of trenches, wherein the third trench is spaced apart from the second trench of the plurality of trenches in the first direction; and a dielectric layer formed between the first conductive layer and the second conductive layer, wherein a portion of interlayer insulating layer is disposed between the second conductive layer and the third conductive layer, and wherein a first width of the first conductive layer in the first direction is greater than a second width of the second conductive layer in the first direction.

According to an embodiment of the present inventive concept, an integrated circuit device includes an interconnection structure, wherein the interconnection structure includes: a lower conductive layer formed on a substrate; an interlayer insulating layer formed on the lower conductive layer and having a first trench therein; a first via layer passing through portions of the interlayer insulating layer under the first trench; a first conductive layer electrically connected to the lower conductive layer through the first via layer; a second conductive layer formed on a second via layer, wherein the second via layer is spaced apart from the first via layer in a first direction; a third conductive layer formed on a third via layer, wherein the third via layer is spaced apart from the second via layer in the first direction; and a dielectric layer formed between the first conductive layer and the second conductive layer, wherein a portion of the interlayer insulating layer is formed between the second conductive layer and the third conductive layer, and wherein a first width of the first conductive layer in the first direction is greater than a second width of the second conductive layer in the first direction.

According to an embodiment of the present inventive concept, an integrated circuit device includes an interconnection structure, wherein the interconnection structure includes: an interlayer insulating layer arranged on a substrate and having a plurality of trenches formed in the interlayer insulating layer, wherein the interlayer insulating layer includes silicon oxide; a first conductive layer formed inside a first trench of the plurality of trenches; a second conductive layer formed inside a second trench of the plurality of trenches, wherein the second trench is spaced apart from the first trench of the plurality of trenches in a first direction; a third conductive layer formed inside a third trench of the plurality of trenches, wherein the third trench is spaced apart from the second trench of the plurality of trenches in the first direction; and a dielectric layer formed between the first conductive layer and the second conductive layer and including silicon nitride, silicon oxynitride (SiON), silicon carbon nitride (SiCN), aluminum oxide (Al₂O₂), aluminum nitride (AlN), titanium oxide (TiO₂), or a combination thereof, which have an etch selectivity with respect to the interlayer insulating layer, wherein the interlayer insulating layer includes silicon oxide, and a portion of the interlayer insulating layer is formed between the second conductive layer and the third conductive layer, wherein a first width of the first conductive layer in the first direction is greater than a second width of the second conductive layer in the first direction, and a first separation distance between the first conductive layer and the second conductive layer in the first direction is less than or equal to a second separation distance between the second conductive layer and the third conductive layer in the first direction.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view illustrating an interconnection structure of an integrated circuit device according to an embodiment of the present inventive concept;

FIG. 2 is a cross-sectional view of the interconnection structure of the integrated circuit device taken along a line X-X′ of FIG. 1;

FIG. 3 is an enlarged view of portion “A” of FIG. 2;

FIG. 4 is a cross-sectional view illustrating an interconnection structure of an integrated circuit device according to an embodiment of the present inventive concept;

FIG. 5 is a cross-sectional view illustrating an interconnection structure of an integrated circuit device according to an embodiment of the present inventive concept;

FIG. 6 is a cross-sectional view illustrating an interconnection structure of an integrated circuit device according to an embodiment of the present inventive concept; and

FIGS. 7, 8, 9, 10, 11, 12, 13, 14 and 15 are cross-sectional views illustrating a process of manufacturing the interconnection structure of the integrated circuit device shown in FIG. 1 according to an embodiment of the present inventive concept.

### DETAILED DESCRIPTION OF THE EMBODIMENTS

Hereinafter, embodiments of the present inventive concept will be described in detail with reference to the accompanying drawings. However, the present inventive concept is not intended to be limited to the embodiments set forth herein and may be embodied in different forms.

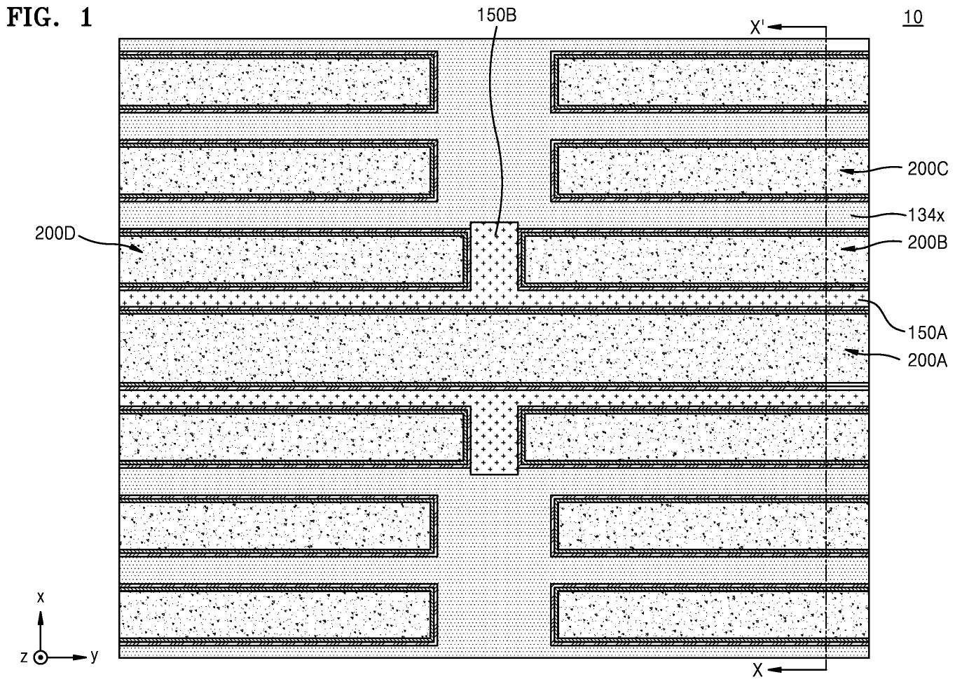

FIG. 1 is a cross-sectional view illustrating an interconnection structure 10 of an integrated circuit device according to an embodiment of the present inventive concept.

Referring to FIG. 1, the interconnection structure 10 of the integrated circuit device may include a plurality of electrode structures 200A, 200B, 200C, and 200D, and dielectric layers 150A and 150B and a second interlayer insulating layer 134x, which are formed between the plurality of electrode structures 200A, 200B, 200C, and 200D. The plurality of electrode structures 200A, 200B, and 200C may be spaced apart from each other in a first direction (e.g., an x-direction) on a substrate. The width, in the first direction, of the first electrode structure 200A may be largest among the plurality of electrode structures 200A, 200B, and 200C. The widths of the second electrode structure 200B and the third electrode structure 200C may be substantially the same as each other. FIG. 1 illustrates that seven electrode structures are arranged. However, the number of electrode structures is not limited to the above-described number.

The second electrode structure 200B and the fourth electrode structure 200D may be spaced apart from each other in a second direction (e.g., a y-direction) substantially perpendicular to the first direction on the substrate.

According to an embodiment of the present inventive concept, a first direction (e.g., the x-direction) distance between the first electrode structure 200A and the second electrode structure 200B may less than a first direction (e.g., the x-axis direction) distance between other electrode structures of plurality of electrode structures 200B, 200C, and 200D. The dielectric layer 150A may be formed between the first electrode structure 200A and the second electrode structure 200B, and the dielectric layer 150A may include a material having an etch selectivity with respect to the second interlayer insulating layer 134x. Thus, through an etching process using the etch selectivity of the dielectric layer 150A, the first direction (e.g., the x-axis direction) distance between the first electrode structure 200A and the second electrode structure 200B may be relatively small. A detailed description of a process using the etch selectivity of the dielectric layer 150A is provided later.

According to an embodiment of the present inventive concept, a second direction (e.g., a y-axis direction) distance between the second electrode structure 200B and the fourth electrode structure 200D may less than a second direction (e.g., the y-axis direction) distance between other electrode structures of plurality of electrode structures. The dielectric layer 150B may be formed between the second electrode structure 200B and the fourth electrode structure 2001), and the dielectric layer 150B may include a material having an etch selectivity with respect to the second interlayer insulating layer 134x. Thus, through an etching process using the etch selectivity of the dielectric layer 150B, the second direction (e.g., the y-axis direction) distance between the second electrode structure 200B and the fourth electrode structure 200D may be relatively small. A detailed description of a process using the etch selectivity of the dielectric layer 150B is provided later.

FIG. 1 illustrates that a space between the second electrode structure 200B and the fourth electrode structure 200D is greater than each of a space between the first electrode structure 200A and the second electrode structure 200B and/or a space between the second electrode structure 200B and the third electrode structure 200C. However, the present inventive concept is not necessarily limited thereto.

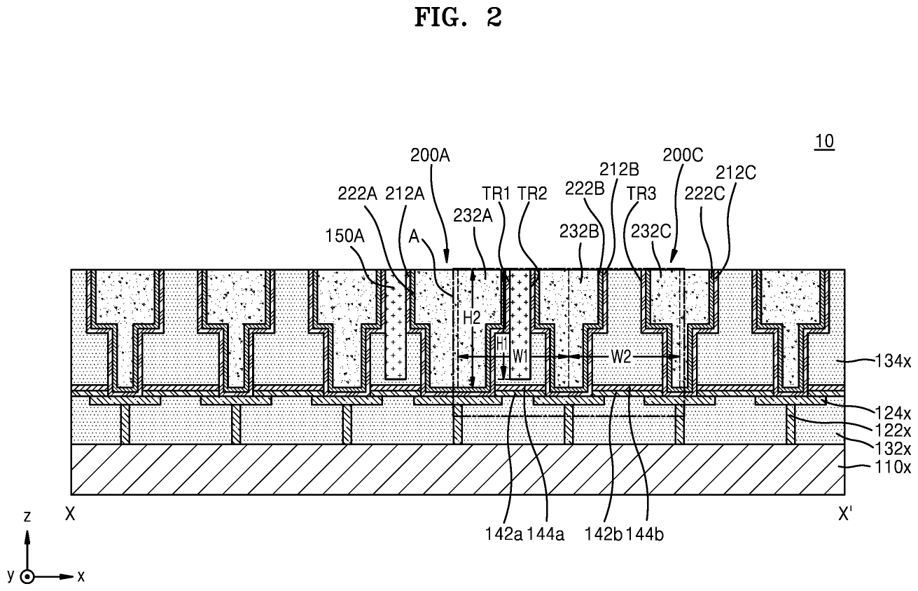

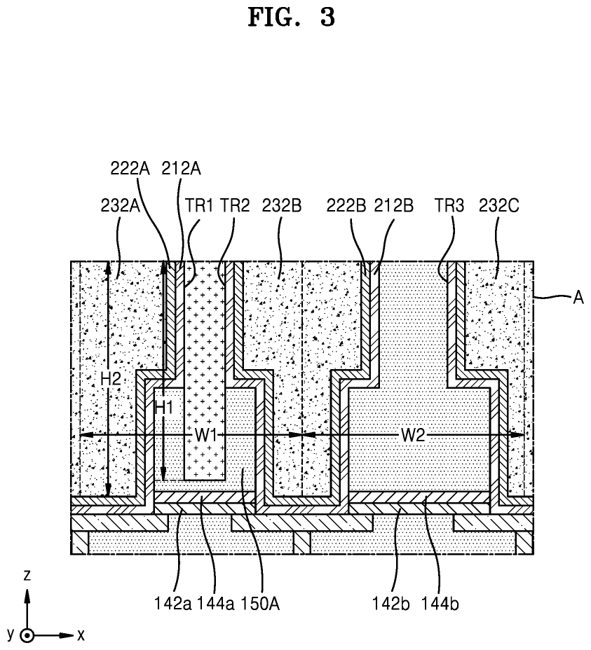

FIG. 2 is a cross-sectional view of the interconnection structure of the integrated circuit device taken along a line X-X of FIG. 1. FIG. 3 is an enlarged view of portion “A” of FIG. 2.

The interconnection structure 10 of the integrated circuit device shown in FIG. 2 may be a dual damascene structure formed by a dual damascene process. For example, a via hole etching process for forming via holes and a trench etching process for forming trenches TR1 TR2, and TR3 may be simultaneously performed on the dual damascene structure.

Referring to FIG. 2, the interconnection structure 10 of the integrated circuit device may include a multi-layered wiring layer for connecting a lower conductive layer 124x to conductive layers 232A, 232B, and 232C. The interconnection structure 10 of the integrated circuit device may include a substrate 110x. For example, the substrate 110x may be formed from a single crystal wafer. The substrate 110x may be, for example, a silicon wafer. Various electronic elements, such as transistors and/or capacitors, may be formed in the substrate 110x.

A first interlayer insulating layer 132x may be formed on the substrate 110x. The first interlayer insulating layer 132x may include, for example, silicon oxide. A conductive plug 122x and the lower conductive layer 124x may be arranged inside the first interlayer insulating layer 132x.

The lower conductive layer 124x may be a conductive material layer formed of at least one of, for example, copper (Cu), tungsten (W), aluminum (Al), or a combination thereof. The conductive plug 122x may be electrically connected to electrical elements formed in the substrate 110x.

A second interlayer insulating layer 134x and etch-stop layers 142a and 144b may be formed on the lower conductive layer 124x. The second interlayer insulating layer 134x may include, for example, silicon oxide. The etch-stop layers 142a and 142b may include materials having an etch selectivity with respect to the second interlayer insulating layer 134x. Thus, the etch-stop layers 142a and 142b may include materials having an etch selectivity with respect to silicon oxide. The etch-stop layers 142a and 144b are shown as double layers for convenience; however, the etch-stop layers 142a and 144b may include a single layer or a plurality of layers having a triple layer or more.

A first trench TR1 may be formed inside the etch-stop layers 142a and 144a and the second interlayer insulating layer 134x. The bottom of the first trench TR1 may be formed at a position lower than that of the bottom surface of the second etch-stop layer 142a. For example, a top surface of the lower conductive layer 124x may be exposed at the bottom portion of the first trench TR1.

Other trenches TR2 and T3 plurality of trenches TR1, TR2 and TR3 may be spaced apart from each other in a first direction based on the first trench TR1. The other trenches TR2 and TR3 may be formed inside the etch-stop layers 142b and 144b and the second interlayer insulating layer 134x.

A first barrier 212A, a first seed layer 222A, and a first conductive layer 232A may be included in the first trench TR1. The first barrier 212A may be formed with a substantially uniform thickness along the surface of the first trench TR1. A second barrier 212B, a second seed layer 222B, and a second conductive layer 232B may be included in the second trench TR2. The second barrier 212B may be formed with a substantially uniform thickness along the surface of the second trench TR2. A third barrier 212C, a third seed layer 222C, and a third conductive layer 232C may be included in the third trench TR3. The third barrier 212C may be formed with a substantially uniform thickness along the surface of the third trench TR3. Each of the first barrier 212A, the second barrier 212B, and the third barrier 212C may include, for example, ruthenium (Ru), cobalt (Co), tantalum (Ta), tantalum nitride (TaN), titanium (Ti), titanium nitride (TiN), tungsten (W), tungsten nitride (WN), ruthenium (Ru), or a combination thereof (e.g., an alloy or a stacked structure). Each of the plurality of barrier layers 212A, 212B, and 212C, may respectively surround the conductive layers 232A, 232B, and 232C, and the dielectric layer 150A may be in contact with a first barrier 212A and a second barrier 212B.

The first seed layer 222A may be formed with a substantially uniform thickness along the surface of the first barrier 212A inside the first trench TR1. The second seed layer 222B may be formed with a substantially uniform thickness along the surface of the second barrier 212B inside the second trench TIC. The third seed layer 222C may be formed with a substantially uniform thickness along the surface of the third barrier 212C inside the third trench TR3. Each of the first seed layer 222A, the second seed layer 222B, and the third seed layer 222C may include, for example, copper (Cu), platinum (Pt), palladium (Pd), nickel (Ni), silver (Ag), ruthenium (Ru), and the like.

The first conductive layer 232A may be formed on the first seed layer 222A and inside the first trench TR1. The first seed layer 222A may at least partially surround the first conductive layer 232A. For example, the bottom surface and both sidewalls of the first conductive layer 232A may be surrounded by the first seed layer 222A. Thus, the first conductive layer 232A may be spaced apart from the dielectric layer 150A so as not to contact the dielectric layer 150A. The first barrier 212A may prevent a material for forming the first conductive layer 232A from being diffused into the first interlayer insulating layer 132x and the lower conductive layer 124x. The first barrier 212A may have conductivity and may be configured to reduce an ohmic resistance of the first conductive layer 232A and the lower conductive layer 124x. The first conductive layer 232. A may include, for example, Cu, Pt, Pd, Ni, Au, Ag, Ru, and the like.

The dielectric layer 150A may be formed between the first conductive layer 232A, which is included in the first electrode structure 200A, and the second conductive layer 232B, which is included in the second electrode structure 200B. The dielectric layer 150A may include a material having an etch selectivity with respect to the interlayer insulating layers 132x and 134x. The dielectric layer 150A may include, for example, silicon nitride (SiN), silicon oxynitride (SiON), silicon carbon nitride (SiCN), aluminum oxide (Al₂O₂), aluminum nitride (AlN), titanium oxide (TiO₂), or a combination thereof. Because the dielectric layer 150A includes a material having an etch selectivity with respect to the interlayer insulating layers 132x and 134x, the dielectric layer 150A may be etched at a relatively low speed or may be hardly etched in a process of etching the interlayer insulating layers 132x and 134x. In addition, the interlayer insulating layers 132x and 134x may be etched at a relatively low speed or may be hardly etched in a process of etching the dielectric layer 150A.

A second conductive layer 232B and a third conductive layer 232C may be spaced apart from each other in a first direction based on the first trench TR1 and may be formed inside the second trench TR2 and the third trench TR3, respectively. The second conductive layer 232B may be formed on the second seed layer 222B and inside the second trench TR2, and the third conductive layer 232C may be formed on the third seed layer 222C and inside the third trench TR31 The second seed layer 222B may at least partially surround the second conductive layer 232B, and the third seed layer 222C may at least partially surround the third conductive layer 232C. For example, the bottom surface and both sidewalls of the second conductive layer 232B may be surrounded by the second seed layer 222B. Thus, the second conductive layer 232B may be spaced apart from the dielectric layer 150A and the second interlayer insulating layer 134x so as not to contact the dielectric layer 150A and the second interlayer insulating layer 134x. As an additional example, the bottom surface and both sidewalls of the third conductive layer 232C may be surrounded by the third seed layer 222C. Thus, the third conductive layer 232C may be spaced apart from the second interlayer insulating layer 134x so as not to contact the second interlayer insulating layer 134x. The second barrier 212B and the third barrier 212C may prevent materials for forming the second conductive layer 232B and the third conductive layer 232C from being diffused into the first and second interlayer insulating layers 132x and 134x and the lower conductive layer 124x that is arranged under the second barrier 212B and the third barrier 212C. The second barrier 212B and the third barrier 212C may have conductivity and may reduce an ohmic resistance between the second conductive layer 232B and the lower conductive layer 124x and an ohmic resistance between the third conductive layer 232C and the lower conductive layer 124x.

According to an embodiment of the present inventive concept, a first width of the first conductive layer 232A included in the first trench TR1 in the first direction (e.g., the x-direction) may be greater than a second width of the second conductive layer 232B included in the second trench TR2. In addition, the second width of the second conductive layer 232B included in the second trench TR2 in the first direction (e.g., the x-direction) may be greater than a third width of the third conductive layer 232C included in the third trench TR3.

According to an embodiment of the present inventive concept, a first distance W1 between the center of the first conductive layer 232A, included in the first trench TR1, in the first direction (e.g., the x-direction) and the center of the second conductive layer 232B, included in the second trench TR2, may be greater than or equal to a second distance W2 between the second conductive layer 232B, included in the second trench TR2, in the first direction (e.g., the x-direction) and the center of the third conductive layer 232C, included in the third trench TR3, in the first direction (e.g., the x-direction).

According to an embodiment of the present inventive concept, based on top surfaces of the first conductive layer 232A and the dielectric layer 150A, a vertical length of the dielectric layer 150A may be less than or equal to a vertical length of the first conductive layer 232A. In this case, the vertical length of the dielectric layer 150A may be less than or equal to each of a vertical length of the second conductive layer 232B and a vertical length of the third conductive layer 232C as well as the vertical length of the first conductive layer 232A.

According to an embodiment of the present inventive concept, a first separation distance between the first conductive layer 232A and the second conductive layer 2323 in the first direction (e.g., the x-direction) may be less than or equal to a second separation distance between the second conductive layer 232B and the third conductive layer 232C in the first direction (e.g., the x-direction). For example, the first separation distance may be a distance between the first electrode structure 200A and the second electrode structure 200B, and the second separation distance may be a distance between the second electrode structure 200B and the third electrode structure 200C. For example, the first separation distance may be a width of the dielectric layer 150A located between the first electrode structure 200A and the second electrode structure 200B, and the second separation distance may be a width of the second interlayer insulating layer 134x located between the second electrode structure 200B and the third electrode structure 200C. In other words, the first separation distance may refer to a distance between tipper sidewalls of the first conductive layer 232A, which face the second conductive layer 232B, and upper sidewalls of the second conductive layer 232B, which face the first conductive layer 232A, or a minimum distance between the first conductive layer 232A and the second conductive layer 232B. In addition, the third separation distance ray refer to a distance between upper sidewalls of the second conductive layer 232B, which face the third conductive layer 232C, and upper sidewalls of the third conductive layer 232C, which face the second conductive layer 232B, or a minimum distance between the second conductive layer 232B and the third conductive layer 232C. The dielectric layer 150A including a material, which has an etch selectivity with respect to the second interlayer insulating layer 134x, between the first electrode structure 200A and the second electrode structure 200B may be formed so that the first separation distance may be less than or equal to the second separation distance. According to an embodiment of the present inventive concept, a width of the dielectric layer 150A in the first direction (e.g., the x-direction) may be smaller than a width of the first conductive layer 232A in the first direction (e.g., the x-direction).

Referring to FIGS. 2 and 3, a second interlayer insulating layer 134x may be formed between the second conductive layer 232B, which is included in the second electrode structure 200B, and the third conductive layer 232C, which is included in the third electrode structure 200C. Based on the center of each of the first conductive layer 232A, the second conductive layer 232B, and the third conductive layer 232C, a distance W1 between the center of the first conductive layer 232A and the center of the second conductive layer 232B may be greater than or equal to a distance W2 between the center of the second conductive layer 232B and the center of the third conductive layer 232C.

In addition, based on top surfaces of the first conductive layer 232A and the dielectric layer 150A, a vertical length H1 of the dielectric layer 150A may be less than or equal to a vertical length H2 of the first conductive layer 232A.

Because the dielectric layer 150A includes a material having an etch selectivity with respect to the interlayer insulating layers 132x and 134x, the dielectric layer 150A may be etched at a relatively low speed or may be hardly etched in a process of etching the interlayer insulating layers 132x and 134x. In addition, the interlayer insulating layers 132x and 134x may be etched at a relatively low speed or may be hardly etched in a process of etching the dielectric layer 150A. Thus, a distance W1 or a first separation distance between the first conductive layer 232A and the second conductive layer 232B may be reduced through a process using an etch selectivity despite the limit of the photolithography process. Thus, the first separation distance between the first conductive layer 232A and the second conductive layer 232B in the first direction (e.g., the x-direction) may be less than or equal to the second separation distance between the second conductive layer 232B and the third conductive layer 232C in the first direction (e.g., the x-direction).

Referring to FIG. 1 together, a fourth electrode structure 2001) may be formed to be spaced apart from the second electrode structure 200B in a second direction (e.g., the y-direction) substantially perpendicular to the first direction (e.g., the x-direction). The fourth electrode structure 200D may further include a fourth conductive layer formed inside a fourth trench. In addition, a dielectric layer 150B may be formed between the second conductive layer 232B and the fourth conductive layer.

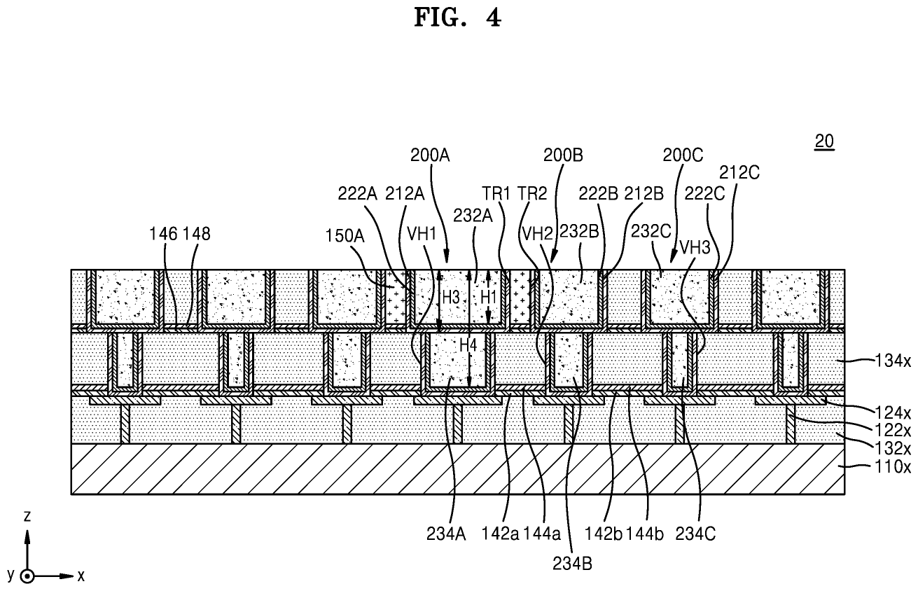

FIG. 4 is a cross-sectional view illustrating an interconnection structure 20 of an integrated circuit device according to an embodiment of the present inventive concept.

The interconnection structure 20 of the integrated circuit device shown in FIG. 4 may be a single damascene structure formed by a single damascene process. The single damascene structure may be formed by performing a via hole etching process, which is for forming via holes VH, and a trench etching process, which is for forming trenches TR separately.

Components shown in FIG. 2 that may be assumed as being similar to components of the interconnection structure 20 of the integrated circuit device shown in FIG. 4 may perform the same or similar functions.

When comparing FIGS. 2 and 4 with each other, same reference numerals may refer to same elements. Thus, a description of the same elements as those of FIG. 2 may be omitted or briefly discussed.

The interconnection structure 20 of the integrated circuit device may pass through portions of the second interlayer insulating layer 134x that is disposed under the plurality of trenches TR1, TR2, and TR3 to form a plurality of via holes VH1, VH2, and VH3 in the second interlayer insulating layer 134x. A plurality of via layers 234A, 234B, and 234C may be formed inside the plurality of via holes VH1, VH2, and VH3. The plurality of conductive layers 232A, 232B, and 232C may be electrically connected to a lower conductive layer 124x through the plurality of via layers 234A, 234B, and 234C, respectively.

A first barrier 212A, a first seed layer 222A, and a first via layer 234A may be formed in the first via hole VH1. The first barrier 212A may be formed with a substantially uniform thickness along the surface of the first via hole VH1, and the first seed layer 222A may be disposed on the first barrier layer 212A. The first via layer 234A may be disposed on the first seed layer 222A. A second barrier 212B, a second seed layer 222B, and a second via layer 234B may be included in the second via hole VH2. The second barrier 212B may be formed with a substantially uniform thickness along the surface of the second via hole VH2, and the second seed layer 222B may be disposed on the second barrier layer 212B. The second via layer 234B may be disposed on the second seed layer 222B. A third barrier 212C, a third seed layer 222C, and a third via layer 234C may be included in the third via hole VH3. The third barrier 212C may be formed with a substantially uniform thickness along the surface of the third via hole VH3, and the third seed layer 222C may be disposed on the third barrier layer 212C. The third via layer 234C may be disposed on the third seed layer 222C.

The second conductive layer 232B may be formed on the second via layer 234B, which is spaced apart from the first via layer 234A in the first direction (e.g., the x-direction). The third conductive layer 232C may be formed on the third via layer 234C that is spaced apart from the second via layer 234B in the first direction (e.g., the x-direction). The dielectric layer 150A may be formed in a space between the first conductive layer 232A and the second conductive layer 232B, and the second interlayer insulating layer 134x may be formed in a space between the second conductive layer 232B and the third conductive layer 232C In this case, a bottom surface of the dielectric layer 150A may be at a higher position than or on the same plane as the top surfaces of the first via layer 234A, the second via layer 234B, and the third via layer 234C. For example, the bottom surface of the dielectric layer 150A may be at a higher position than the top surfaces of the first via layer 234A, the second via layer 234B, and the third via layer 234C. For example, the bottom surface of the dielectric layer 150A may be at a higher position than or on the same plane as the bottom surfaces of the first conductive layer 232A, the second conductive layer 232B, and the third conductive layer 232C. According to an embodiment of the present inventive concept, the bottom surface of the dielectric layer 150A may be at a lower position than the bottom surfaces of the first conductive layer 232A, the second conductive layer 232B, and the third conductive layer 232C.

Based on the center of each of the first conductive layer 232A, the second conductive layer 232B, and the third conductive layer 232C, a distance W1 between the center of the first conductive layer 232A and the center of the second conductive layer 232B may be greater than or equal to a distance W2 between the center of the second conductive layer 232B and the center of the third conductive layer 232C.

In an embodiment of the present inventive concept, the first separation distance between the first conductive layer 232A and the second conductive layer 232B in the first direction (e.g., the x-direction) may be less than or equal to the second separation distance between the second conductive layer 232B and the third conductive layer 232C in the first direction (e.g., the x-direction). Here, the first separation distance may refer to a distance between upper sidewalls of the first conductive layer 232A, which face the second conductive layer 232B, and tipper sidewalls of the second conductive layer 232B, which face the first conductive layer 232A, or a minimum distance between the first conductive layer 232A and the second conductive layer 232B. In addition, the third separation distance may refer to a distance between upper sidewalls of the second conductive layer 232B, which face the third conductive layer 232C, and upper sidewalls of the third conductive layer 232C, which face the second conductive layer 232B, or a minimum distance between the second conductive layer 2323 and the third conductive layer 232C.

Because the dielectric layer 150A includes a material having an etch selectivity with respect to the interlayer insulating layers 132x and 134x, the dielectric layer 150A may be etched at a relatively low speed or may be hardly etched in a process of etching the interlayer insulating layers 132x and 134x. In addition, the interlayer insulating layers 132x and 134x may be etched at a relatively low speed or may be hardly etched in a process of etching the dielectric layer 150A. Thus, a distance W1 or a first separation distance between the first conductive layer 232A and the second conductive layer 232B may be reduced through a process using an etch selectivity despite the limit of the photolithography process.

The dielectric layer 150A may be formed between the first conductive layer 232A included in the first electrode structure 200A and the second conductive layer 232B included in the second electrode structure 200B. The dielectric layer 150A may include a material having an etch selectivity with respect to the interlayer insulating layers 132x and 134x. The dielectric layer 150A may include, for example, SiN, AlN, molybdenum disulfide (MoS₂), hexagonal-Boron nitride, or a combination thereof. Because the dielectric layer 150A includes a material having an etch selectivity with respect to the interlayer insulating layers 132x and 134x, the dielectric layer 150A may be etched at a relatively low speed or may be hardly etched in a process of etching the interlayer insulating layers 132x and 134x. In addition, the interlayer insulating layers 132x and 134x may be etched at a relatively low speed or may be hardly etched in a process of etching the dielectric layer 150A.

A second interlayer insulating layer 134x and etch-stop layers 142b and 144b may be formed on the lower conductive layer 124x and the first interlayer insulating layer 132x. The etch-stop layers 142b and 144b may be arranged in a space between the first via layer 234A and the second via layer 234B and in a space between the second via layer 234B and the third via layer 234C. The second interlayer insulating layer 134x may include, for example, a silicon oxide. The etch-stop layers 142a and 142b may include materials having an etch selectivity with respect to the second interlayer insulating layer 134x. Thus, the etch-stop layers 142a and 142b may include materials having an etch selectivity with respect to silicon oxide. The etch-stop layers 142a and 144b are shown as double layers for convenience, however, may include a single layer or a plurality of layers having a triple layer or more.

Upper etch-stop layers 146 and 148 may be formed on the second interlayer insulating layer 134x. The upper etch-stop layers 146 and 148 may be arranged in a space between the plurality of trenches TR1, TR2, and TR3. The second interlayer insulating layer 134x may include, for example, a silicon oxide. The upper etch-stop layers 146 and 148 may include materials having an etch selectivity with respect to the second interlayer insulating layer 134x. Thus, the upper etch-stop layers 146 and 148 may include materials having an etch selectivity with respect to silicon oxide. The upper etch-stop layers 146 and 148 are shown as double layers for convenience, however, may include a single layer or a plurality of layers having a triple layer or more.

In an embodiment of the present inventive concept, the second interlayer insulating layer 134x may include a first sub insulating layer, in which the plurality of via holes VH1, VH2, and VH3 may be formed, and a second sub insulating layer, in which the plurality of trenches TR1, TR2 and TR3 may be formed.

A first trench TR1 may be formed inside the upper etch-stop layers 146 and 148 and the second interlayer insulating layer 134x. The bottom of the first trench TR1 may be formed on the same plane as the bottom surface of the first upper etch-stop layer 146 or at a position lower than the bottom surface of the first upper etch-stop layer 146. The first trench TR1 may vertically overlap the first via hole VH1. The first trench TR1 may be a trench recessed from the top surface of the second interlayer insulating layer 134x to a level substantially equal to a level of the bottom surface of the first upper etch-stop layer 146 by a third height H3. The combined height of the first trench TR1 and the first via hole VH1 may extend from the top surface of the second interlayer insulating layer 134x to the top surface of lower conductive layer 124x and may be a fourth height H4.

Second and third trenches TR2 and TR3 may be spaced apart from each other in the first direction (x-direction) based on the first trench TR1. The second and third trenches TR2 and TR3 may be formed inside the tipper etch-stop layers 146 and 148 and the second interlayer insulating layer 134x. The second and third trenches TR2 and TR3 may vertically overlap the second via hole VH2 and the third via hole VH3, respectively.

A first barrier 212A, a first seed layer 222A, and a first conductive layer 232A may be included in the first trench TR1. The first barrier 212A may be formed with a substantially uniform thickness along the surface of the first trench TR1. A second barrier 212B, a second seed layer 222B, and a second conductive layer 232B may be included in the second trench TR2. The second barrier 212B may be formed with a substantially uniform thickness along the surface of the second trench TR2. A third barrier 212C, a third seed layer 222C, and a third conductive layer 232C may be included in the third trench TR3. The third barrier 212C may be formed with a substantially uniform thickness along the surface of the third trench TR3. The first barrier 212A, the second barrier 212B, and the third barrier 212C: may each include, for example, ruthenium (Ru), cobalt (Co), tantalum (Ta), tantalum nitride (TaN) titanium (Ti), titanium nitride (TiN), tungsten (W), tungsten nitride (WN), ruthenium (Ru), or a combination thereof (e.g., an alloy or a stacked structure). Each of the plurality of barrier layers 212A, 212B, and 212C; may at least partially surround the conductive layers 232A, 232B, and 232C, and the dielectric layer 150A may come into contact with a first barrier 212A and a second barrier 212B.

Referring to FIG. 1 together, a fourth electrode structure 200D may be formed to be spaced apart from the second electrode structure 200B in a second direction (e.g., the y-direction) substantially perpendicular to the first direction (e.g., the x-direction). The fourth electrode structure 200D may further include a fourth conductive layer formed inside a fourth trench that is overlapping a fourth via hole that is filled with a fourth via layer. For example, a fourth conductive layer may be formed on the fourth via layer spaced apart from the second via layer 234B in the second direction (e.g., the y-direction) substantially perpendicular to the first direction (e.g., the x-direction). In addition, a dielectric layer 150B may be formed between the second conductive layer 232B and the fourth conductive layer.

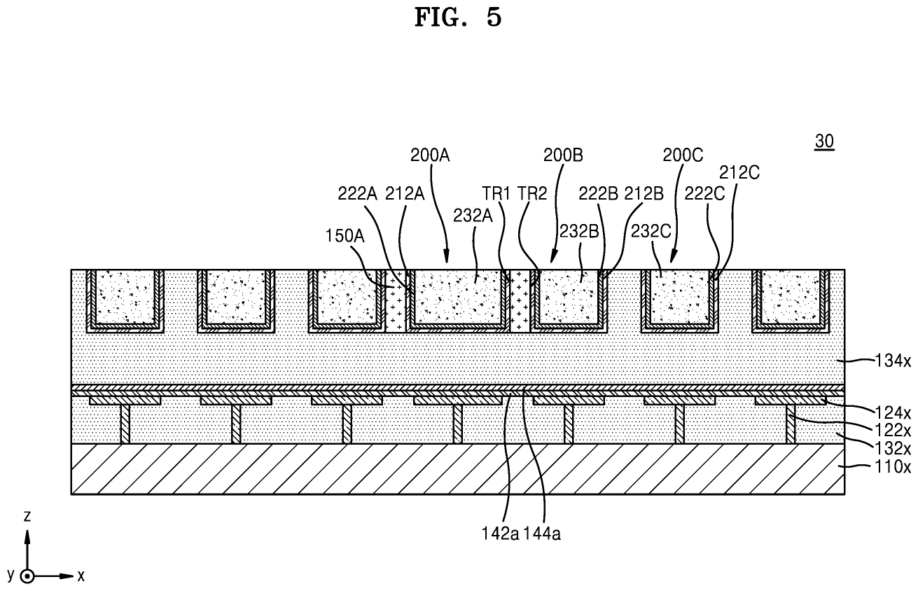

FIG. 5 is a cross-sectional view illustrating an interconnection structure 30 of an integrated circuit device according to an embodiment of the present inventive concept.

For example, the interconnection structure 30 of the integrated circuit device may be substantially the same as the interconnection structure 10 of the integrated circuit device of FIGS. 1 to 4, except that the interconnection structure 30 does not include a via layer. The reference numerals of FIG. 5 that are the same as those of FIGS. 1 through 4 refer to same elements. Thus, a description of the same elements as those of FIGS. 1 through 4 may be briefly described or omitted.

According to an embodiment of the present inventive concept, the interconnection structure 30 of the integrated circuit device may include an interlayer insulating layer 134x formed on the lower etch-stop layers 142a and 144b. A plurality of trenches TR1, TR2, and TR3 may be formed inside the interlayer insulating layer 134x, and conductive layers 232A, 232B, and 232C may be respectively formed inside the plurality of trenches TR1, TR2, and TR3.

The plurality of trenches TR1, TR2, and TR3 may be spaced apart from the lower etch-stop layers 142a and 142b. The interconnection structure 30 of the integrated circuit device may include a dielectric layer 150A having an etch selectivity with respect to the interlayer insulating layer 134x between the first conductive layer 232A, which is formed inside the first trench TR1, and the second conductive layer 232B, which is formed inside the second trench TR2.

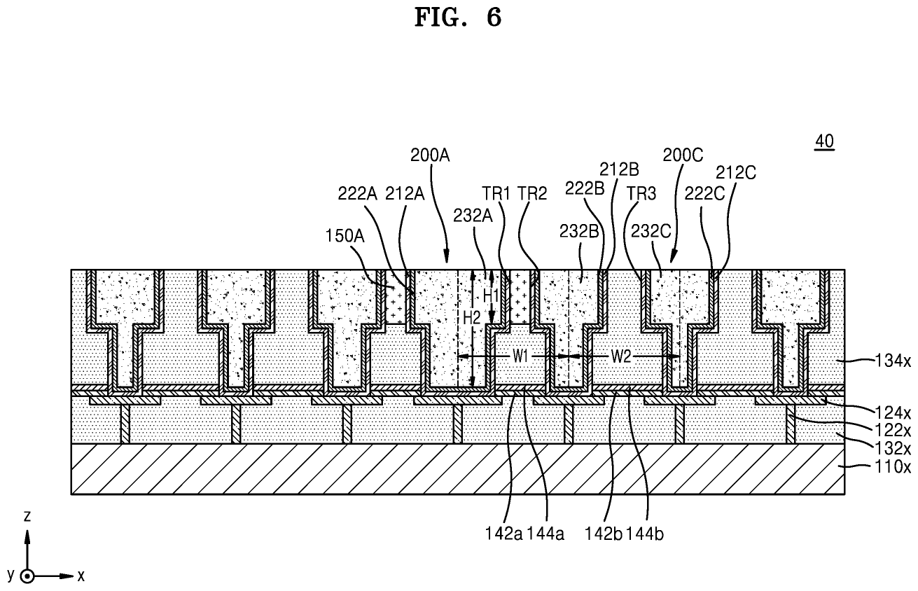

FIG. 6 is a cross-sectional view illustrating an interconnection structure 40 of an integrated circuit device according to an embodiment of the present inventive concept.

For example, the interconnection structure 40 of the integrated circuit device may be substantially the same as the interconnection structure 10 of the integrated circuit device of FIGS. 1 to 4, except that the height of the dielectric layer 150A is relatively small. The reference numerals of FIG. 6 that are the same as those of FIGS. 1 through 4 refer to the same elements. Thus, a description of the same element as those of FIGS. 1 through 3 may be briefly described or omitted.

According to an embodiment of the present inventive concept, the interconnection structure 40 of the integrated circuit device may include a dielectric layer 150A having an etch selectivity with respect to the interlayer insulating layer 134x between the first conductive layer 232A, which is formed inside the first trench TR1, and the second conductive layer 232B, which is formed inside the second trench TR2. In this case, the lower cross-section of the dielectric layer 150A may be at a higher position than upper cross-sections of lower etch-stop layers 142a and 144b.

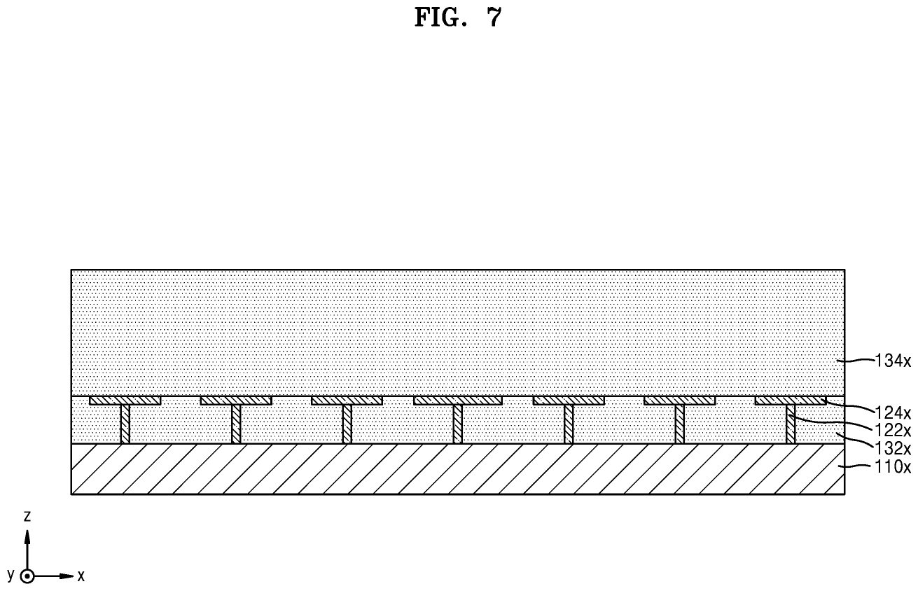

FIGS. 7 through 15 are cross-sectional views for illustrating a process of manufacturing the interconnection structure 10 of the integrated circuit device shown in FIG. 1 according to an embodiment of the present inventive concept.

Referring to FIG. 7, a first interlayer insulating layer 132x may be formed on a semiconductor substrate 110x. The first interlayer insulating layer 132x may include, for example, silicon oxide. A conductive plug 122x and a lower conductive layer 124x may be arranged inside the first interlayer insulating layer 132x.

In an embodiment of the present inventive concept, the lower conductive layer 124x may be a conductive material layer including W or Al. In an embodiment of the present inventive concept, the lower conductive layer 124x may be a conductive material layer including Cu. The conductive plug 122x may be electrically connected to electrical elements formed in the substrate 110x.

A second interlayer insulating layer 134x and etch-stop layers 142a and 144b may be formed on the first conductive layer 107. The second interlayer insulating layer 109 and the third interlayer insulating layer 123 may include, for example, silicon oxide layers. The etch-stop layers 142a and 144a may include materials having an etch selectivity with respect to the second interlayer insulating layer 134x. The etch-stop layers 142a and 144a may, for example, include silicon nitride layers.

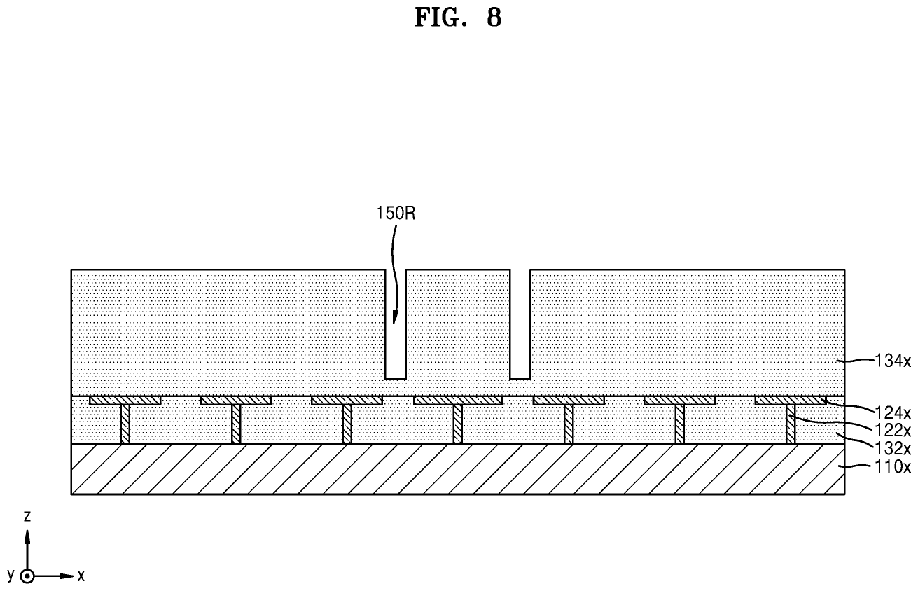

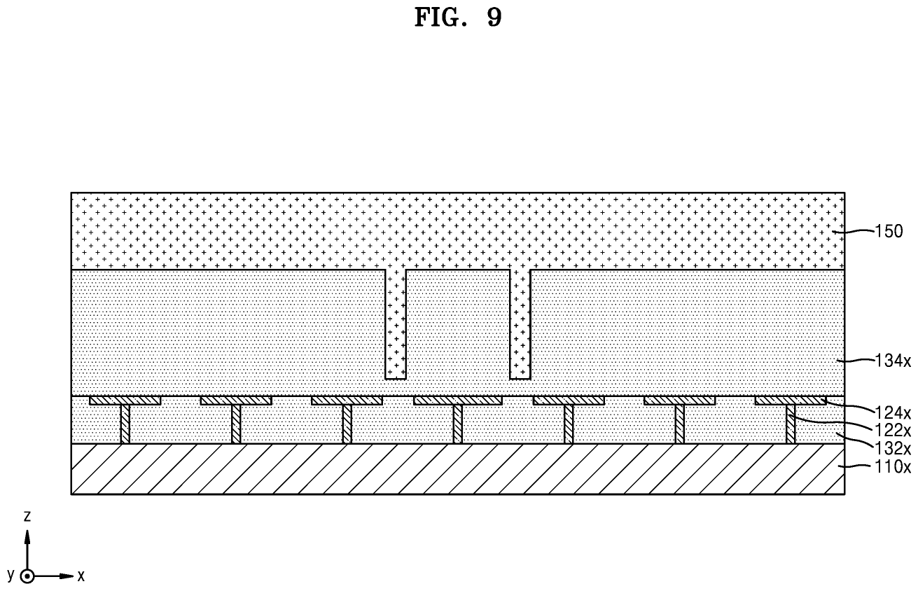

Referring to FIGS. 8 and 9, a recess region 150R in which a dielectric layer 150 may be formed, may be formed by removing portions of the second interlayer insulating layer 134x. In FIG. 8, two recess regions are formed. However, embodiments of the present inventive concept are not limited to the above-described number, and three or more recess regions may be formed. The recess region 150R may be formed by using photography and etching methods. The recess region 150R may be formed by trench first via last (TFVL) or via first trench last (VFTL).

After the recess region 150R is formed, the dielectric layer 150 may be deposited on sidewalls of the recess region 150R and the second interlayer insulating layer 134x. The dielectric layer 150 may be formed by using physical vapor deposition (PVD), chemical vapor deposition (CVD), plasma-enhanced CVD, or atomic layer deposition (ALD). The dielectric layer 150 may include a material having an etch selectivity with respect to the second interlayer insulating layer 134x. The dielectric layer 150 may include, for example, silicon nitride (SiN), silicon oxynitride (SiON), silicon carbon nitride (SiCN), aluminum oxide (Al₂O₂), aluminum nitride (AlN), titanium oxide (TiO₂), or a combination thereof.

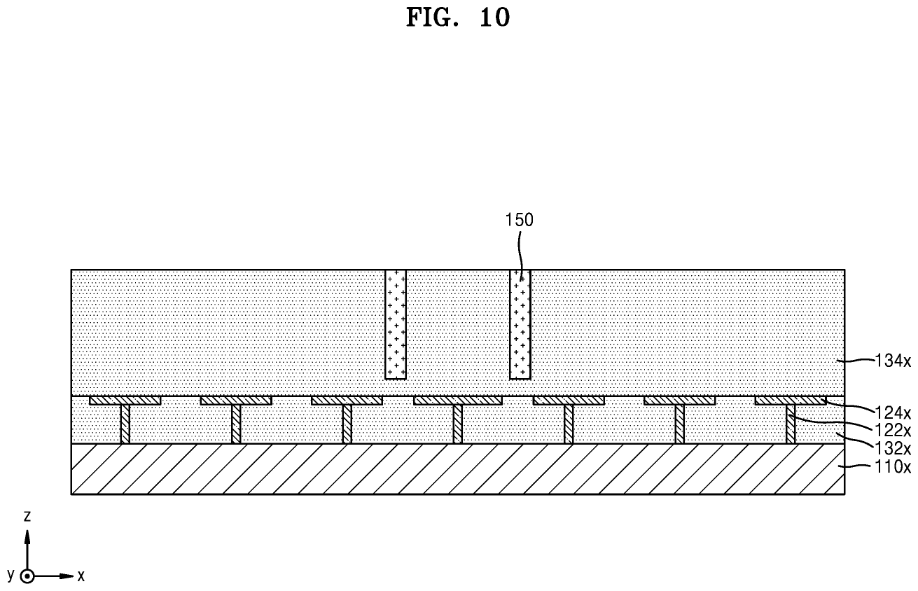

Referring to FIG. 10, the dielectric layer 150 deposited on the second interlayer insulating layer 134x may be etched A process of etching the dielectric layer 150 may be a process using an etch selectivity. For example, while the second interlayer insulating layer 134x is hardly removed, the dielectric layer 150 may be etched at a relatively high speed. Thus, the dielectric layer 150 may be completely etched, and only the second interlayer insulating layer 134x may be exposed in the region of the second interlayer insulating layer 134x in which no recess is formed.

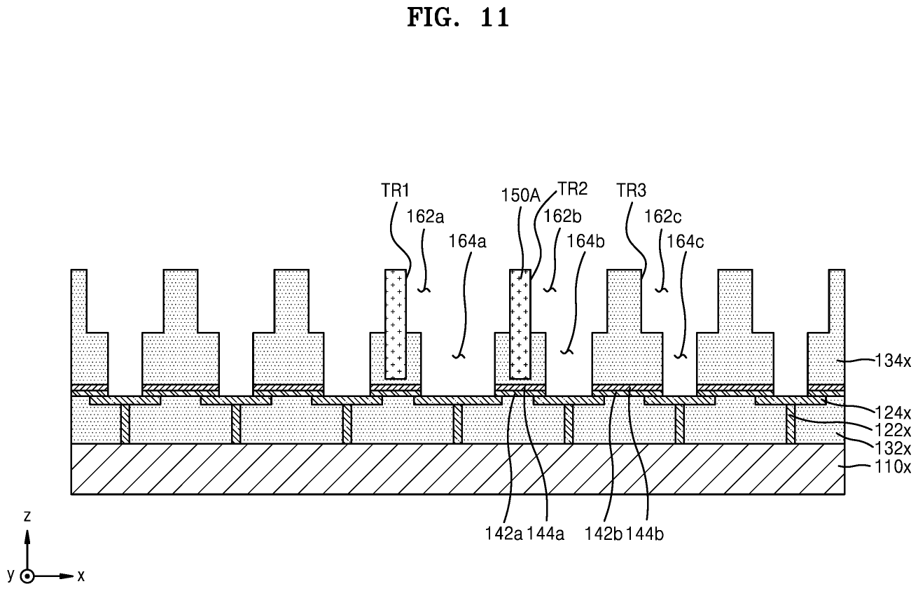

Referring to FIG. 11, by etching portions of the second interlayer insulating layer 134x and the dielectric layer 150, a first upper recess region 162a formed between a plurality of dielectric layers 150, a second tipper recess region 162b formed between the dielectric layer 150 and the second interlayer insulating layer 134x, and a third upper recess region 162c formed between a plurality of second interlayer insulating layers 134x may be formed.

In an embodiment of the present inventive concept, a process of etching portions of the second interlayer insulating layer 134x and a process of etching portions of the dielectric layer 150 may be different processes. The process of etching portions of the second interlayer insulating layer 134x and the process of etching portions of the dielectric layer 150 may be processes using an etch selectivity.

For example, the process of etching the second interlayer insulating layer 134x may be performed first, and the second interlayer insulating layer 134x may be etched at a relatively high speed while the dielectric layer 150 is hardly removed. The process of etching portions of the dielectric layer 150 may be performed after the process of etching the second interlayer insulating layer 134x is performed. While the second interlayer insulating layer 134x is hardly removed, the dielectric layer 150 may be etched at a relatively high speed.

Because the dielectric layer 150 includes a material having an etch selectivity with respect to the interlayer insulating layers 132x and 134x, the dielectric layer 150 may be etched at a relatively low speed or may be hardly etched in a process of etching the interlayer insulating layers 132x and 134x. In addition, the interlayer insulating layers 132x and 134x may be etched at a relatively low speed or may be hardly etched in the process of etching the dielectric layer 150. Thus, a distance between the first conductive layer 232A and the second conductive layer 232B may be reduced through a process using an etch selectivity despite the limit of the photolithography process.

Subsequently, portions of the dielectric layer 150 may be etched to laterally expand a first upper recess region 162a between the plurality of dielectric layers 150. The process of etching portions of the dielectric layer 150 may be a process using an etch selectivity. The width of the first upper recess region 162a formed between the plurality of dielectric layers 150 may be greater than a width of the second upper recess region 162b formed between the dielectric layer 150 and the second interlayer insulating layer 134x and/or a width of the third upper recess region 162c formed between the plurality of second interlayer insulating layers 134x.

Subsequently, portions of the second interlayer insulating layer 134x may be etched to form lower recess regions 164a, 164b, and 164c. The first lower recess region 164a may be formed between portions of the plurality of dielectric layers 150. The second lower recess region 164b may be formed between portions of the dielectric layer 150 and portions of the second interlayer insulating layer 134x. The third lower recess region 164c may be formed between portions of the plurality of second interlayer insulating layers 134x. The first lower recess region 164a, the second lower recess region 164b, and the third lower recess region 164c may have, for example, shapes of holes each having a circular horizontal cross-sectional shape. Each of widths of the first lower recess region 164a, the second lower recess region 164b, and the third lower recess region 164c may be less than each of widths of the first upper recess region 162a, the second upper recess region 162b, and the third upper recess region 162c.

Subsequently, portions of the dielectric layer 150 may be etched to form the first trench TR1. For example, portions of the dielectric layer 150 may be etched to laterally expand the first lower recess region 164a between the plurality of dielectric layers 150. In this case, the first trench TR1 may be a region including the first upper recess region 162a and the first lower recess region 164a. The second trench TR2 may be a region including the second upper recess region 162b and the second lower recess region 164b. The third trench TR3 may be a region including the third upper recess region 162c and the third lower recess region 164c.

The second trench TR2 may be spaced apart from the first trench TR1 in the first direction (e.g., the x-direction). The third trench TR3 may be spaced apart from the second trench TR2 in the first direction (e.g., the x-direction). The first trench TR1 may at least partially surround portions of the dielectric layer 150 and portions of the second interlayer insulating layer 134x. The second trench TR2 may at least partially surround portions of the dielectric layer 150 and portions of the second interlayer insulating layer 134x. The third trench TR3 may at least partially surround portions of the second interlayer insulating layer 134x.

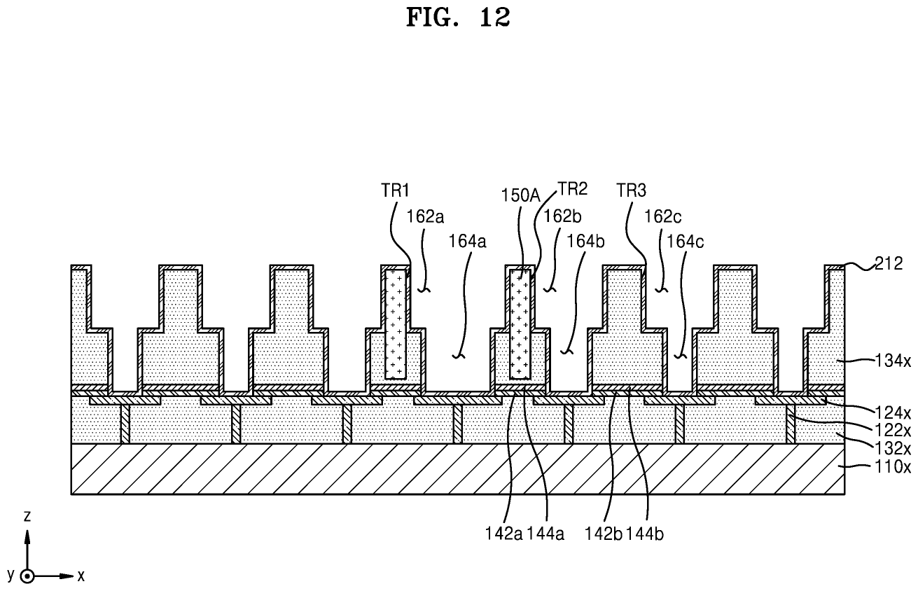

Referring to FIG. 12, a barrier 212 may be formed on the uppermost surface of the dielectric layer 150 and sidewalls and bottom (e.g., bottom surface) of the first trench TR1. In addition, the barrier 212 may be formed on the uppermost surface of the second interlayer insulating layer 134x, the sidewalls and bottom of the second trench TR2, and the sidewalls and the bottom of the third trench TR3. The barrier 212 may be formed using, for example, PVD, CVD, plasma-enhanced CVD, or ALD. The barrier 212 may include ruthenium (Ru), cobalt (Co), tantalum (Ta), tantalum nitride (TaN), titanium (Ti), titanium nitride (TiN), W, tungsten nitride (WN), or a combination thereof (e.g., an alloy or stack structure).

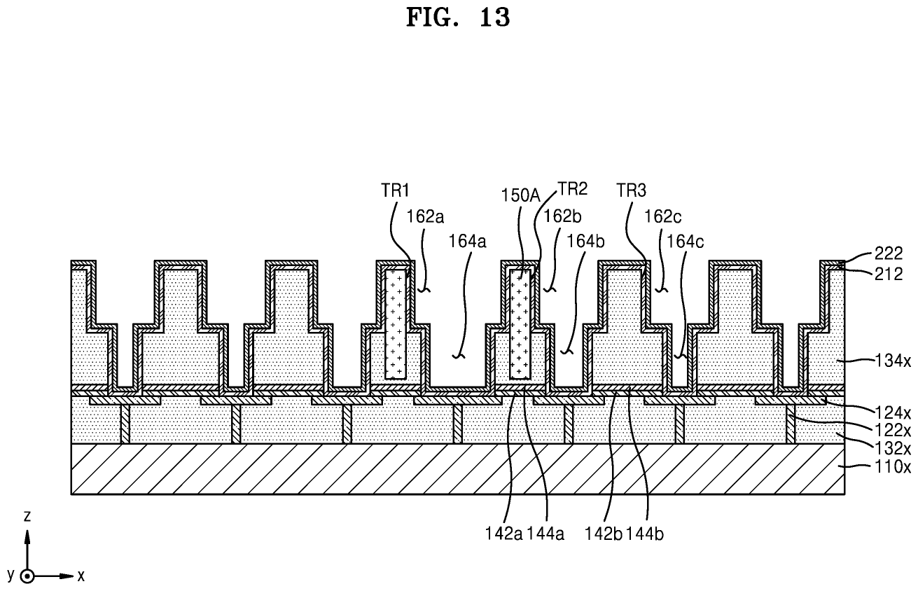

Referring to FIG. 13, a seed layer 222 may be formed on the barrier 212. The seed layer 222 may be formed using, for example, PVD, CVD, plasma-enhanced CVD, or ALD. The seed layer 222 may include Cu, Pt, Pd, Ni, Au, Ag, Ru, and the like.

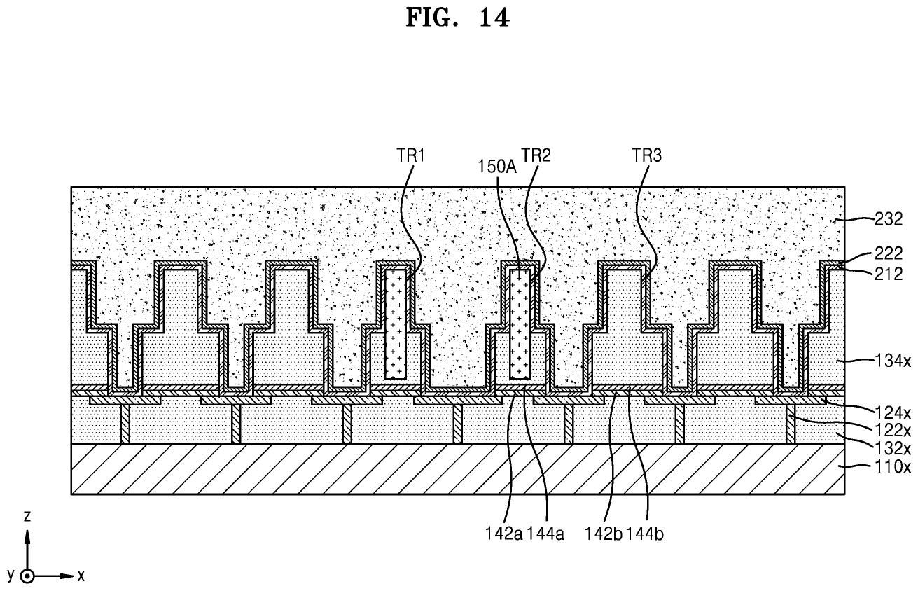

Referring to FIG. 14, a conductive layer 232 may be formed on the seed layer 222. The conductive layer 232 may fill the first trench TR1, the second trench TR2, and the third TR3.

The seed layer 222 may serve to facilitate the formation of the conductive layer 232. The conductive layer 232 may be formed using, for example, electroplating or PVD, CVD, plasma-enhanced CVD, or ALD. The conductive layer 232 may include at least one of, for example, Cu, Pt, Pd, Ni, Au, Ag, Ru, and the like.

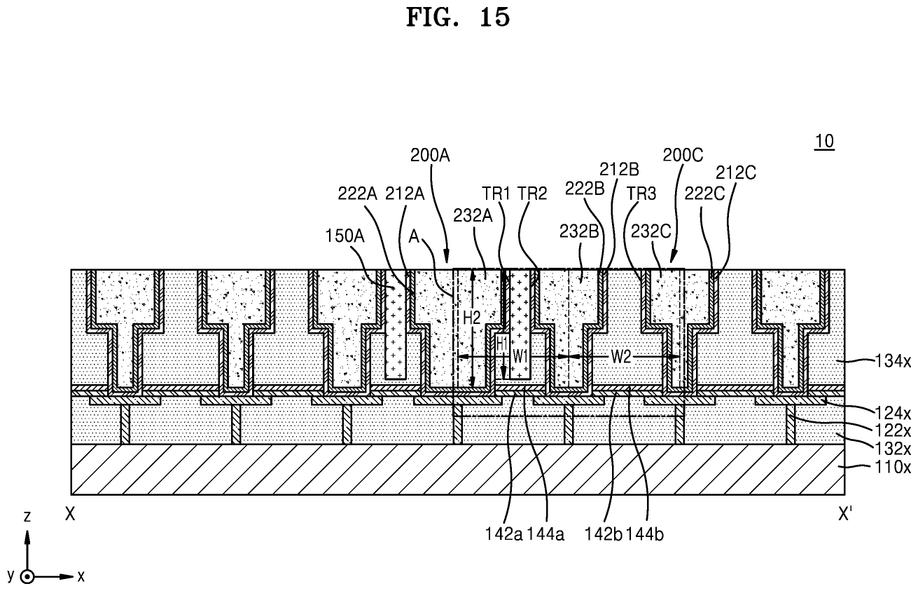

Referring to FIG. 15, the barrier 212, the seed layer 222, and the conductive layer 232 may be planarized using etch back or chemical mechanical polishing (CMP) to form a first electrode structure 200A, a second electrode structure 200B, and a third electrode structure 200C. The first electrode structure 200A may be arranged between portions of the plurality of dielectric layers 150A. The first electrode structure 200A may include a first barrier 212A, a first seed layer 222A formed on the first barrier 212A, and a first conductive layer 232A formed on the first seed layer 222A. The second electrode structure 200B may be arranged between portions of the dielectric layer 150 and portions of the second interlayer insulating layer 134x. The second electrode structure 200B may include a second barrier 212B, a second seed layer 222B formed on the second barrier 212B, and a second conductive layer 232B formed on the second seed layer 222B. The third electrode structure 200C may be arranged between portions of the second interlayer insulating layer 134x. The third electrode structure 200C may include a third barrier 212C, a third seed layer 222C formed on the third barrier 212C, and a third conductive layer 232C formed on the third seed layer 222C.

As described above, embodiments of the present inventive concept have been disclosed in the drawings and the specification. Although embodiments have been described in the specification by using specific terms, this is merely used for the purpose of describing embodiments of the present inventive concept and is not used to limit the scope of the present inventive concept.

While the present inventive concept has been described with reference to embodiments thereof, it will be understood by those of ordinary skill in the art that various changes in form and details may be made thereto without departing from the spirit and scope of the present inventive concept.

What is claimed is:

1. An integrated circuit device comprising an interconnection structure, wherein the interconnection structure comprises:
an interlayer insulating layer arranged on a substrate and having a plurality of trenches formed in the interlayer insulating layer;
a first conductive layer formed inside a first trench of the plurality of trenches;
a second conductive layer formed inside a second trench of the plurality of trenches, wherein the second trench is spaced apart from the first trench of the plurality of trenches in a first direction;
a third conductive layer formed inside a third trench of the plurality of trenches, wherein the third trench is spaced apart from the second trench of the plurality of trenches in the first direction; and
a dielectric layer formed between the first conductive layer and the second conductive layer,
wherein a portion of interlayer insulating layer is disposed between the second conductive layer and the third conductive layer, and
wherein a first width of the first conductive layer in the first direction is greater than a second width of the second conductive layer in the first direction.

2. The integrated circuit device of claim 1, wherein the dielectric layer comprises a material having an etch selectivity with respect to the interlayer insulating layer.

3. The integrated circuit device of claim 1, wherein a first distance between a center of the first conductive layer in the first direction and a center of the second conductive layer in the first direction is greater than or equal to a second distance between a center of the second conductive layer in the first direction and a center of the third conductive layer in the first direction.

4. The integrated circuit device of claim 1, wherein, based on top surfaces of the first conductive layer and the dielectric layer, a vertical length of the dielectric layer is less than or equal to a vertical length of the first conductive layer.

5. The integrated circuit device of claim 1, wherein the interlayer insulating layer comprises silicon oxide.

6. The integrated circuit device of claim 1, wherein the dielectric layer comprises silicon nitride (SiN), silicon oxynitride (SiON), silicon carbon nitride (SiCN), aluminum oxide (Al₂O₂), aluminum nitride (AlN), titanium oxide (TiO₂), or a combination thereof.

7. The integrated circuit device of claim 1, further comprising a fourth conductive layer formed inside a fourth trench of the plurality of trenches, wherein the fourth trench is spaced apart from the second trench of the plurality of trenches in a second direction substantially perpendicular to the first direction, wherein the dielectric layer is formed between the second conductive layer and the fourth conductive layer.

8. The integrated circuit device of claim 1, further comprising a first seed layer and a second seed layer, wherein the first seed layer at least partially surrounds the first conductive layer, wherein the second seed layer at least partially surrounds the second conductive layer, and wherein the dielectric layer covers the first seed layer and the second seed layer.

9. The integrated circuit device of claim 1, wherein a first separation distance between the first conductive layer and the second conductive layer in the first direction is less than or equal to a second separation distance between the second conductive layer and the third conductive layer in the first direction.

10. An integrated circuit device comprising an interconnection structure, wherein the interconnection structure comprises:
a lower conductive layer formed on a substrate;
an interlayer insulating layer formed on the lower conductive layer and having a first trench therein;
a first via layer passing through portions of the interlayer insulating layer under the first trench;
a first conductive layer electrically connected to the lower conductive layer through the first via layer;
a second conductive layer formed on a second via layer, wherein the second via layer is spaced apart from the first via layer in a first direction;
a third conductive layer formed on a third via layer, wherein the third via layer is spaced apart from the second via layer in the first direction; and
a dielectric layer formed between the first conductive layer and the second conductive layer,
wherein a portion of the interlayer insulating layer is formed between the second conductive layer and the third conductive layer, and
wherein a first width of the first conductive layer in the first direction is greater than a second width of the second conductive layer in the first direction.

11. The integrated circuit device of claim 10, wherein the dielectric layer comprises a material having an etch selectivity with respect to the interlayer insulating layer.

12. The integrated circuit device of claim 10, further comprising a first seed layer and a second seed layer, wherein the first seed layer at least partially surrounds the first conductive layer, wherein the second seed layer at least partially surrounds the second conductive layer, and wherein the dielectric layer covers the first seed layer and the second seed layer.

13. The integrated circuit device of claim 10, wherein a bottom surface of the dielectric layer is at a higher position than a bottom surface of the first via layer.

14. The integrated circuit device of claim 10, wherein a width of the dielectric layer in the first direction is smaller than a width of the first conductive layer in the first direction.

15. The integrated circuit device of claim 10, wherein a first separation distance between the first conductive layer and the second conductive layer in the first direction is less than or equal to a second separation distance between the second conductive layer and the third conductive layer in the first direction.

16. The integrated circuit device of claim 10, wherein the interlayer insulating layer comprises silicon oxide.

17. The integrated circuit device of claim 10, wherein the dielectric layer comprises silicon nitride (SiN), silicon oxynitride (SiON), silicon carbon nitride (SiCN), aluminum oxide (Al₂O₂), aluminum nitride (AlN), titanium oxide (TiO₂), or a combination thereof.

18. The integrated circuit device of claim 10, further comprising a fourth conductive layer formed on a fourth via layer, wherein the fourth via layer is spaced apart from the second via layer in a second direction substantially perpendicular to the first direction, wherein the dielectric layer is formed between the second conductive layer and the fourth conductive layer.

19. An integrated circuit device comprising an interconnection structure, wherein the interconnection structure comprises:
an interlayer insulating layer arranged on a substrate and having a plurality of trenches formed in the interlayer insulating layer, wherein the interlayer insulating layer includes silicon oxide;
a first conductive layer formed inside a first trench of the plurality of trenches;
a second conductive layer formed inside a second trench of the plurality of trenches, wherein the second trench is spaced apart from the first trench of the plurality of trenches in a first direction;
a third conductive layer formed inside a third trench of the plurality of trenches, wherein the third trench is spaced apart from the second trench of the plurality of trenches in the first direction; and
a dielectric layer formed between the first conductive layer and the second conductive layer and including silicon nitride, silicon oxynitride (SiON), silicon carbon nitride (SiCN), aluminum oxide (Al₂O₂), aluminum nitride (AlN), titanium oxide (TiO₂), or a combination thereof, which have an etch selectivity with respect to the interlayer insulating layer,
wherein the interlayer insulating layer includes silicon oxide, and a portion of the interlayer insulating layer is formed between the second conductive layer and the third conductive layer,
wherein a first width of the first conductive layer in the first direction is greater than a second width of the second conductive layer in the first direction, and
a first separation distance between the first conductive layer and the second conductive layer in the first direction is less than or equal to a second separation distance between the second conductive layer and the third conductive layer in the first direction.

20. The integrated circuit device of claim 19, further comprising a fourth conductive layer formed inside a fourth trench of the plurality of trenches, wherein the fourth trench is spaced apart from the second trench of the plurality of trenches in a second direction substantially perpendicular to the first direction, wherein the dielectric layer is formed between the second conductive layer and the fourth conductive layer.
